(19) United States
(12) Patent Application Publication
(10) Pub. No.: US 2015/0162380 A1
(43) Pub. Date: Jun. 11, 2015

(54) MEMORY DEVICE AND METHOD FOR MANUFACTURING THE SAME

(71) Applicant: Kabushiki Kaisha Toshiba, Minato-ku (JP)

(72) Inventors: Kiyohito Nishihara, Mie-ken (JP); Masumi Saitoh, Kanagawa-ken (JP)

(73) Assignee: Kabushiki Kaisha Toshiba, Minato-ku (JP)

(21) Appl. No.: 14/206,597

(22) Filed: Mar. 12, 2014

Related U.S. Application Data
(60) Provisional application No. 61/913,041, filed on Dec. 6, 2013.

(51) Int. Cl. H01L 27/24; G11C 13/00; H01L 45/00; H01L 23/538

(52) U.S. Cl. CPC H01L 27/2463; H01L 23/5386; G11C 13/0002; H01L 45/06; H01L 45/148; H01L 45/1253; H01L 45/16

(57) ABSTRACT

According to one embodiment, a memory device includes a first interconnect having a divided portion formed in the first interconnect, a memory cell member provided on the first interconnect, a second interconnect provided on the memory cell member, a semiconductor member provided on the first interconnect to be connected between portions of the first interconnect on two sides of the divided portion, an insulating film covering an upper surface of the semiconductor member and a side surface of at least an upper portion of the semiconductor member, and an electrode provided on the insulating film to cover the upper surface of the semiconductor member and the side surface of the at least an upper portion of the semiconductor member with the insulating film interposed.

### CROSS-REFERENCE TO RELATED APPLICATIONS

This application is based upon and claims the benefit of priority from U.S. Provisional Patent Application 61/913,041, filed on Dec. 6, 2013; the entire contents of which are incorporated herein by reference.

### FIELD

Embodiments described herein relate generally to a memory device and a method for manufacturing the same.

### BACKGROUND

In recent years, a cross-point memory device in which a two-terminal memory cell member is connected between an interconnect extending in a first direction and an interconnect extending in a second direction has been proposed. In such a memory device, there are cases where switching elements are interposed at the interconnects.

### BRIEF DESCRIPTION OF THE DRAWINGS

FIG. 1A is a plan view illustrating a memory device according to a first embodiment; FIG. 1B is a cross-sectional view along line A-A′ shown in FIG. 1A; and FIG. 1C is a cross-sectional view along line B-B′ shown in FIG. 1A;

FIG. 2A is a plan view illustrating a method for manufacturing the memory device according to the first embodiment; and FIG. 2B is a cross-sectional view along line A-A′ shown in FIG. 2A;

FIG. 3A and FIG. 3B are cross-sectional views illustrating the method for manufacturing the memory device according to the first embodiment;

FIG. 4A is a plan view illustrating the method for manufacturing the memory device according to the first embodiment; and FIG. 4B is a cross-sectional view along line A-A′ shown in FIG. 4A;

FIG. 5A and FIG. 5B are cross-sectional views illustrating the method for manufacturing the memory device according to the first embodiment and show mutually-orthogonal cross sections;

FIG. 6A and FIG. 6B are cross-sectional views illustrating the method for manufacturing the memory device according to the first embodiment and show mutually-orthogonal cross sections;

FIG. 7A and FIG. 7B are cross-sectional views illustrating the method for manufacturing the memory device according to the first embodiment and show mutually-orthogonal cross sections;

FIG. 8A is a plan view illustrating the method for manufacturing the memory device according to the first embodiment; FIG. 8B is a cross-sectional view along line A-A′ shown in FIG. 8A; and FIG. 8C is a cross-sectional view along line B-B′ shown in FIG. 8A;

FIG. 9A and FIG. 9B are cross-sectional views illustrating an operations of the memory device according to the first embodiment and show mutually-orthogonal cross sections;

FIG. 10A and FIG. 10B are cross-sectional views illustrating operations of a memory device according to a modification of the first embodiment and show mutually-orthogonal cross sections;

FIG. 11 is a plan view illustrating a memory device according to a second embodiment;

FIG. 12 is a cross-sectional view along line A-A′ shown in FIG. 11;

FIG. 13 is a cross-sectional view illustrating a memory device according to a first modification of the second embodiment; and

FIG. 14 is a cross-sectional view illustrating a memory device according to a second modification of the second embodiment.

### DETAILED DESCRIPTION

According to one embodiment, a memory device includes a first interconnect having a divided portion formed in the first interconnect, a memory cell member provided on the first interconnect, a second interconnect provided on the memory cell member, a semiconductor member provided on the first interconnect to be connected between portions of the first interconnect on two sides of the divided portion, an insulating film covering an upper surface of the semiconductor member and a side surface of at least an upper portion of the semiconductor member, and an electrode provided on the insulating film to cover the upper surface of the semiconductor member and the side surface of the at least an upper portion of the semiconductor member with the insulating film interposed.

According to one embodiment, a method is disclosed for manufacturing a memory device. The method can include forming a first interconnect, a divided portion being formed in the first interconnect. The method can include forming a semiconductor member on the first interconnect to be connected between portions of the first interconnect on two sides of the divided portion, and forming a memory cell member on a portion of the first interconnect separated from the divided portion. The method can include forming an inter-layer insulating film between the semiconductor member and the memory cell member to expose an upper surface of the memory cell member, an upper surface of the semiconductor member, and a side surface of at least an upper portion of the semiconductor member. The method can include forming an insulating film on the exposed surfaces of the semiconductor member, and forming a second interconnect on the memory cell member, and forming an electrode on the insulating film.

Various embodiments will be described hereinafter with reference to the accompanying drawings.

### First Embodiment

First, a first embodiment will be described.

The memory device according to the embodiment is a nonvolatile memory device, and more specifically, a resistance random access memory device having a cross-point structure.

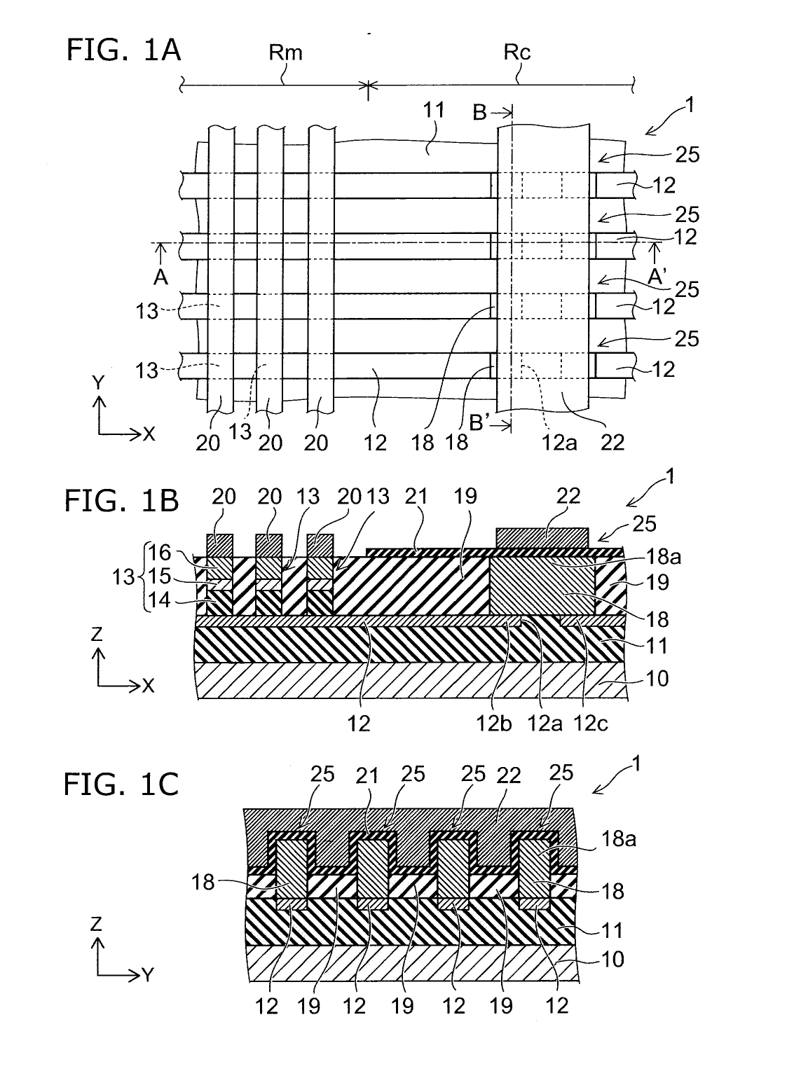

FIG. 1A is a plan view illustrating the memory device according to the embodiment; FIG. 1B is a cross-sectional view along line A-A′ shown in FIG. 1A; and FIG. 1C is a cross-sectional view along line B-B′ shown in FIG. 1A.

As shown in FIG. 1A to FIG. 1C, a semiconductor substrate 10 that is made of, for example, silicon is provided in the memory device 1 according to the embodiment. A memory cell region Rm and a peripheral circuit region Rc are set at the upper surface of the semiconductor substrate 10.

An inter-layer insulating film 11 is provided on the semiconductor substrate 10. The inter-layer insulating film 11 is formed of, for example, silicon oxide. Multiple word lines 12 are provided at the upper layer portion of the inter-layer insulating film 11 to extend in one direction (hereinbelow, called the “X-direction”) parallel to the upper surface of the inter-layer insulating film 11. The word lines 12 are formed of, for example, tungsten (W) or molybdenum (Mo).

A divided portion 12a is made at one location of each of the word lines 12 in the peripheral circuit region Rc. A portion of the inter-layer insulating film 11 is disposed inside the divided portion 12a. Portions 12b and 12c of the word line 12 on the two sides of the divided portion 12a are separated from each other by the divided portion 12a. The divided portions 12a of the multiple word lines 12 are at the same position in the X-direction. Hereinbelow, a direction parallel to the upper surface of the inter-layer insulating film 11 and orthogonal to the X-direction is called the “Y-direction;” and a direction orthogonal to both the X-direction and the Y-direction, i.e., the vertical direction, is called the “Z-direction.”

In the memory cell region Rm, multiple memory cell members 13 are provided on each of the word lines 12. When viewed from the Z-direction, the memory cell members 13 are arranged in a matrix configuration along the X-direction and the Y-direction. The configuration of each of the memory cell members 13 is a pillar configuration extending in the Z-direction; and a resistance change layer 14, a metal supply layer 15, and a stopper layer 16 are stacked in order from the lower side in each of the memory cell members 13. The resistance change layer 14 is formed of, for example, polysilicon. The metal supply layer 15 is formed of a metal that is capable of moving through the resistance change layer 14, e.g., silver (Ag), copper (Cu), nickel (Ni), aluminum (Al), or titanium (Ti). The stopper layer 16 is formed of, for example, tungsten (W).

In the peripheral circuit region Rc, a semiconductor member 18 is provided in a region directly above the divided portion 12a of the word line 12 and the portions 12b and 12c of the word line 12 on the two sides of the word line 12. Thereby, the same number of semiconductor members 18 as word lines 12 are arranged in one column along the Y-direction. The configuration of each of the semiconductor members 18 is, for example, a rectangular parallelepiped having the X-direction as the longitudinal direction. The semiconductor member 18 is formed of, for example, silicon that substantially does not include an impurity. The two X-direction end portions of the semiconductor member 18 contact the portion 12b and the portion 12c of the word line 12. Therefore, the semiconductor member 18 is connected between the portion 12b and the portion 12c of the word line 12.

An inter-layer insulating film 19 is provided above the inter-layer insulating film 11 and the word line 12. The inter-layer insulating film 19 is formed of, for example, silicon oxide. The inter-layer insulating film 19 is disposed between the memory cell members 13, between the semiconductor members 18, and between the memory cell members 13 and the semiconductor members 18. The inter-layer insulating film 19 covers the side surfaces of the memory cell member 13, the side surfaces of the semiconductor member 18 facing the X-direction, and the sides surfaces of the lower portion of the semiconductor member 18 facing the Y-direction, but does not cover the upper surface of the memory cell member 13, the upper surface of the semiconductor member 18, or the side surfaces of an upper portion 18a of the semiconductor member 18 facing the Y-direction. Therefore, the upper surface of the memory cell member 13, the upper surface of the semiconductor member 18, and the upper surface of the portion of the inter-layer insulating film 19 other than the portion between the semiconductor members 18 are portions of the same plane; but the upper surface of the portion of the inter-layer insulating film 19 disposed between the semiconductor members 18 is positioned to be lower than the periphery of the portion to make a recess. In FIG. 1A, the inter-layer insulating film 19 is not shown for easier viewing of the drawing.

In the memory cell region Rm, multiple bit lines 20 are provided on the inter-layer insulating film 19 and the memory cell members 13 to extend in the Y-direction. The bit lines 20 are formed of, for example, tungsten or molybdenum. Each of the bit lines 20 passes through a region directly above the memory cell members 13 arranged in one column along the Y-direction. Thereby, the memory cell members 13 are connected between the word lines 12 and the bit lines 20.

In the peripheral circuit region Rc, a gate insulating film 21 is provided on the inter-layer insulating film 19 and the semiconductor member 18. The gate insulating film 21 is formed of, for example, silicon oxide. The gate insulating film 21 covers the upper surface of the inter-layer insulating film 19 and the upper portion 18a of the semiconductor member 18, i.e., the upper surface and Y-direction-facing side surfaces of the portion of the semiconductor member 18 that protrudes from the upper surface of the inter-layer insulating film 19. A portion of the inter-layer insulating film 19 is disposed between the inter-layer insulating film 11 and the gate insulating film 21 and between the word line 12 and the gate insulating film 21. In FIG. 1A, the gate insulating film 21 is not shown for easier viewing of the drawing.

A gate electrode 22 that extends in the Y-direction is provided on the gate insulating film 21. The gate electrode 22 covers the upper surface and Y-direction-facing side surfaces of the upper portion 18a of the semiconductor member 18 with the gate insulating film 21 interposed. As described below, the gate electrode 22 and the bit lines 20 are formed by patterning the same conductive film. Accordingly, the composition of the gate electrode 22 is equal to the composition of the bit lines 20; and the thickness of the gate electrode 22 is equal to the thickness of the bit lines 20.

A method for manufacturing the memory device according to the embodiment will now be described.

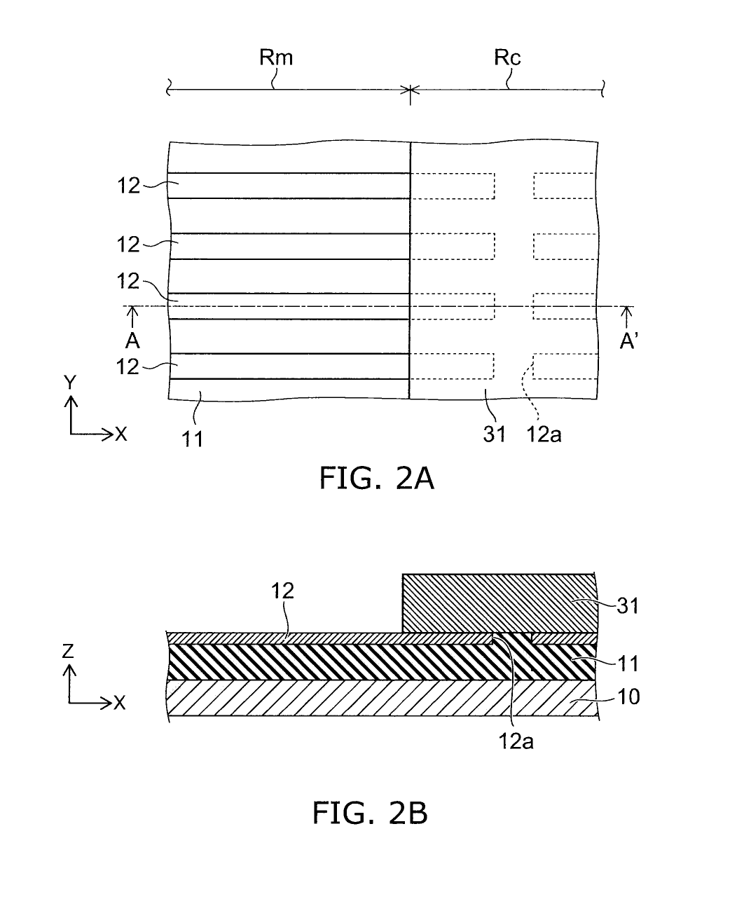

FIG. 2A is a plan view illustrating the method for manufacturing the memory device according to the embodiment; and FIG. 2B is a cross-sectional view along line A-A′ shown in FIG. 2A.

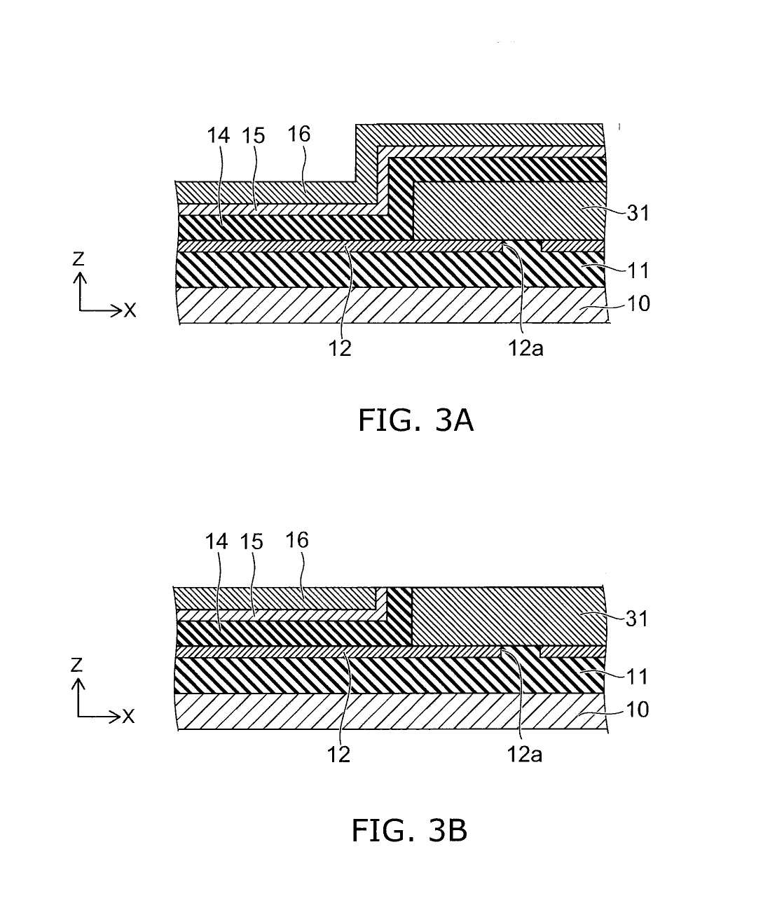

FIG. 3A and FIG. 3B are cross-sectional views illustrating the method for manufacturing the memory device according to the embodiment.

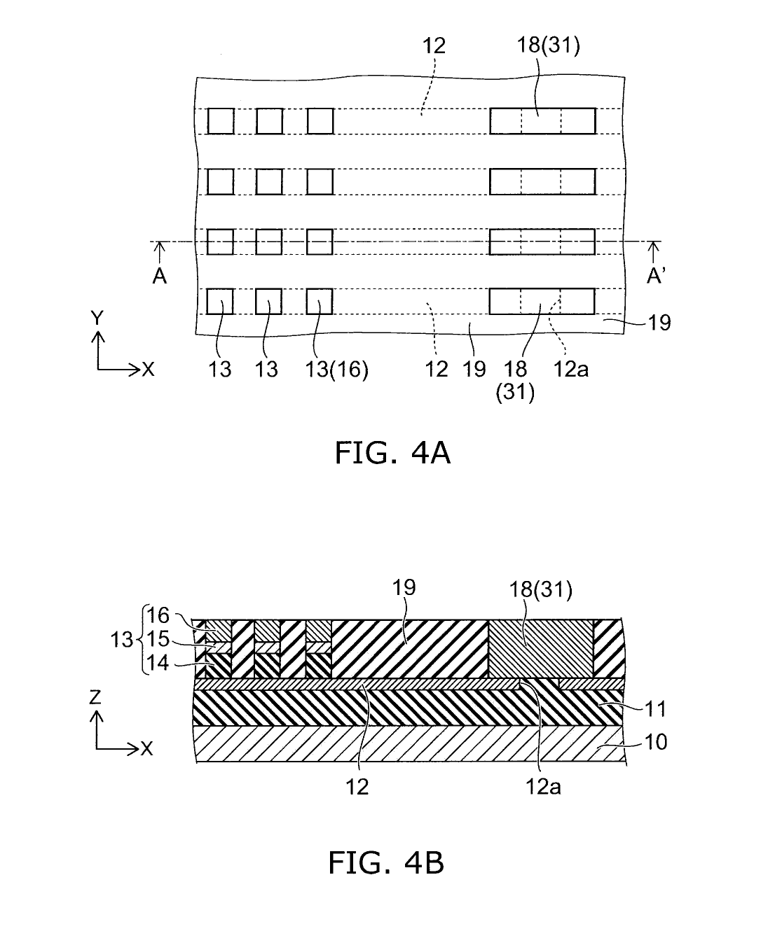

FIG. 4A is a plan view illustrating the method for manufacturing the memory device according to the embodiment; and FIG. 4B is a cross-sectional view along line A-A′ shown in FIG. 4A.

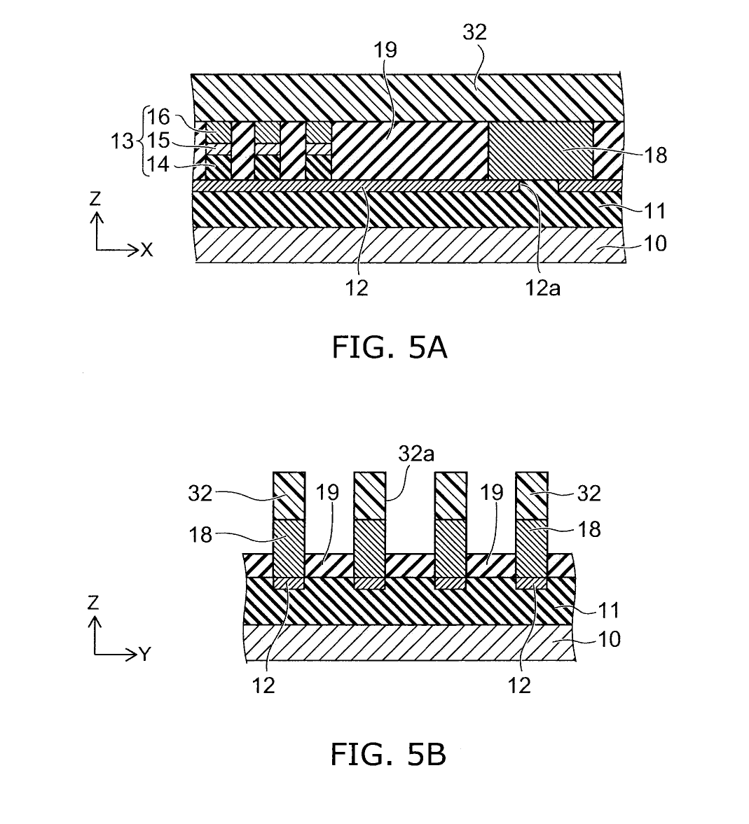

FIG. 5A and FIG. 5B are cross-sectional views illustrating the method for manufacturing the memory device according to the embodiment and show mutually-orthogonal cross sections.

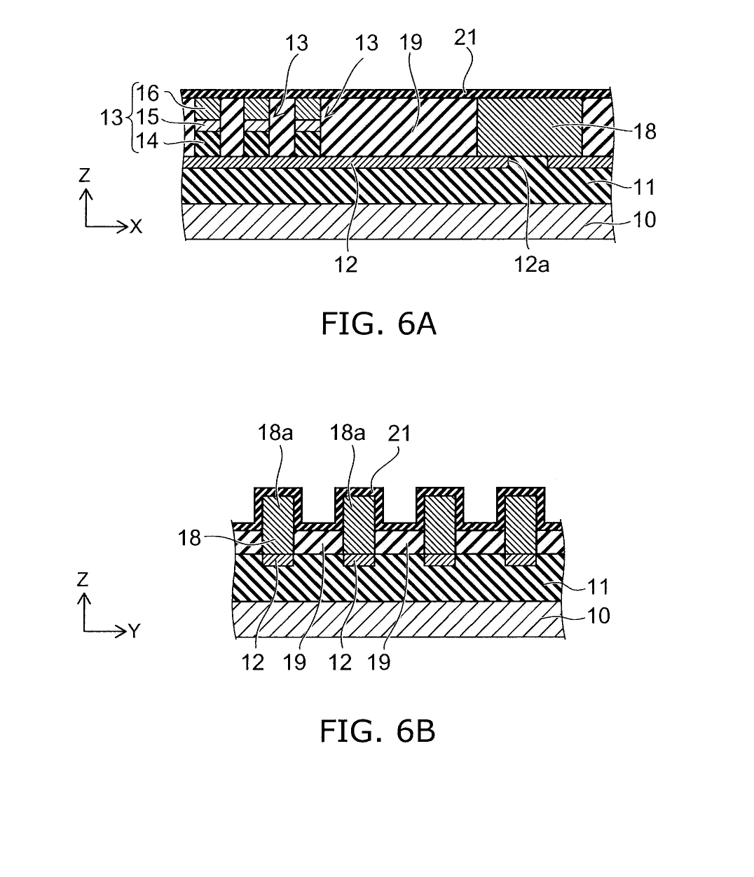

FIG. 6A and FIG. 6B are cross-sectional views illustrating the method for manufacturing the memory device according to the embodiment and show mutually-orthogonal cross sections.

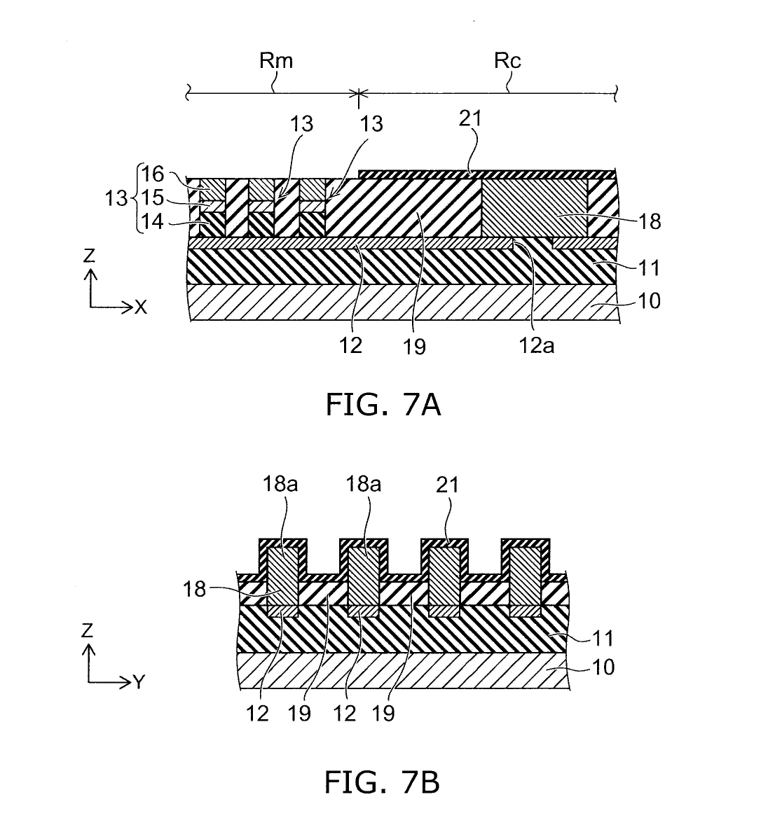

FIG. 7A and FIG. 7B are cross-sectional views illustrating the method for manufacturing the memory device according to the embodiment and show mutually-orthogonal cross sections.

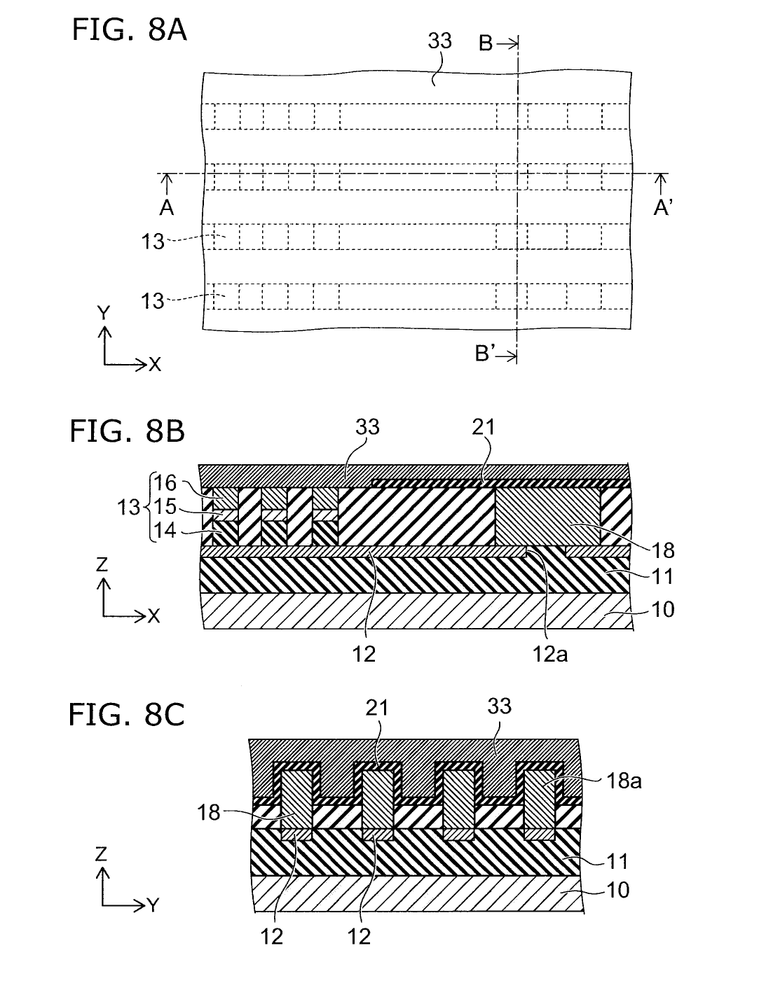

FIG. 8A is a plan view illustrating the method for manufacturing the memory device according to the embodiment; FIG. 8B is a cross-sectional view along line A-A′ shown in FIG. 8A; and FIG. 8C is a cross-sectional view along line B-B′ shown in FIG. 8A.

First, as shown in FIG. 2A and FIG. 2B, the semiconductor substrate 10 is prepared. The memory cell region Rm and the peripheral circuit region Rc are set at the upper surface of the semiconductor substrate 10. Then, the inter-layer insulating film 11 and the word lines 12 are formed on the semiconductor substrate 10. The word line 12 is disposed to extend in the X-direction at the upper layer portion of the inter-layer insulating film 11; and the divided portion 12a is made at one location inside the peripheral circuit region Rc. Then, a silicon film 31 is formed in the peripheral circuit region Rc by depositing silicon, which does not have an added impurity, above the inter-layer insulating film 11 and the word line 12 and by selectively removing the silicon.

Then, as shown in FIG. 3A, the resistance change layer 14, the metal supply layer 15, and the stopper layer 16 are formed in this order on the entire surface. At this time, the resistance change layer 14, the metal supply layer 15, and the stopper layer 16 extend onto the silicon film 31 in the peripheral circuit region Rc.

Then, as shown in FIG. 3B, planarization is performed by CMP (chemical mechanical polishing), etc., using the portion of the stopper layer 16 disposed in the memory cell region Rm as a stopper. Thereby, the resistance change layer 14, the metal supply layer 15, and the stopper layer 16 that are on the silicon film 31 are removed.

Then, as shown in FIG. 4A and FIG. 4B, the multiple memory cell members 13 are formed at portions in regions directly above the word lines 12 by selectively removing the stopper layer 16, the metal supply layer 15, and the resistance change layer 14; and the multiple semiconductor members 18 are formed to straddle the divided portions 12a of the word lines 12 by selectively removing the silicon film 31. Then, the inter-layer insulating film 19 is filled between the memory cell members 13, between the semiconductor members 18, and between the memory cell members 13 and the semiconductor members 18 by depositing an insulating material on the entire surface and performing CMP using the stopper layer 16 as a stopper.

Then, as shown in FIG. 5A and FIG. 5B, a resist pattern 32 is formed above the inter-layer insulating film 19, the memory cell members 13, and the semiconductor members 18. An opening 32a is made in the resist pattern 32 in the regions directly above the portions between the semiconductor members 18. The opening 32a also is made in regions directly above portions at the outward-facing side surfaces of the group of the semiconductor members 18 that are positioned at the two ends of the group of the multiple semiconductor members 18 arranged along the Y-direction. Then, the upper portion of the portion of the inter-layer insulating film 19 between the semiconductor members 18 is removed by performing etching using the resist pattern 32 as a mask. Thereby, the upper portion 18a of the semiconductor member 18 protrudes from the upper surface of the inter-layer insulating film 19. Subsequently, the resist pattern 32 is removed.

Then, as shown in FIG. 6A and FIG. 6B, the gate insulating film 21 is formed on the entire surface. At this time, the gate insulating film 21 is formed on the exposed surfaces of the semiconductor member 18, i.e., on the upper surface of the upper portion 18a and on the side surfaces of the upper portion 18a facing the Y-direction.

Then, as shown in FIG. 7A and FIG. 7B, the gate insulating film 21 is removed from the memory cell region Rm.

Then, as shown in FIG. 8A to FIG. 8C, a conductive film 33 is formed on the entire surface. At this time, the conductive film 33 enters also between the upper portions 18a of the semiconductor members 18.

Then, as shown in FIG. 1A to FIG. 1C, the conductive film 33 is selectively removed. Thereby, the bit lines 20 are formed in the memory cell region Rm to extend in the Y-direction and pass through the regions directly above the memory cell members 13. On the other hand, in the peripheral circuit region Rc, the gate electrode 22 is formed to extend in the Y-direction and pass through the regions directly above the semiconductor members 18. Because the gate electrode 22 remains also between the upper portions 18a of the semiconductor members 18, the gate electrode 22 is disposed on the upper surface of the upper portion 18a and on the side surfaces of the upper portion 18a facing the Y-direction to cover the upper surface and Y-direction-facing side surfaces of the upper portion 18a with the gate insulating film 21 interposed. Thus, the memory device 1 is manufactured.

Operations of the memory device 1 according to the embodiment will now be described.

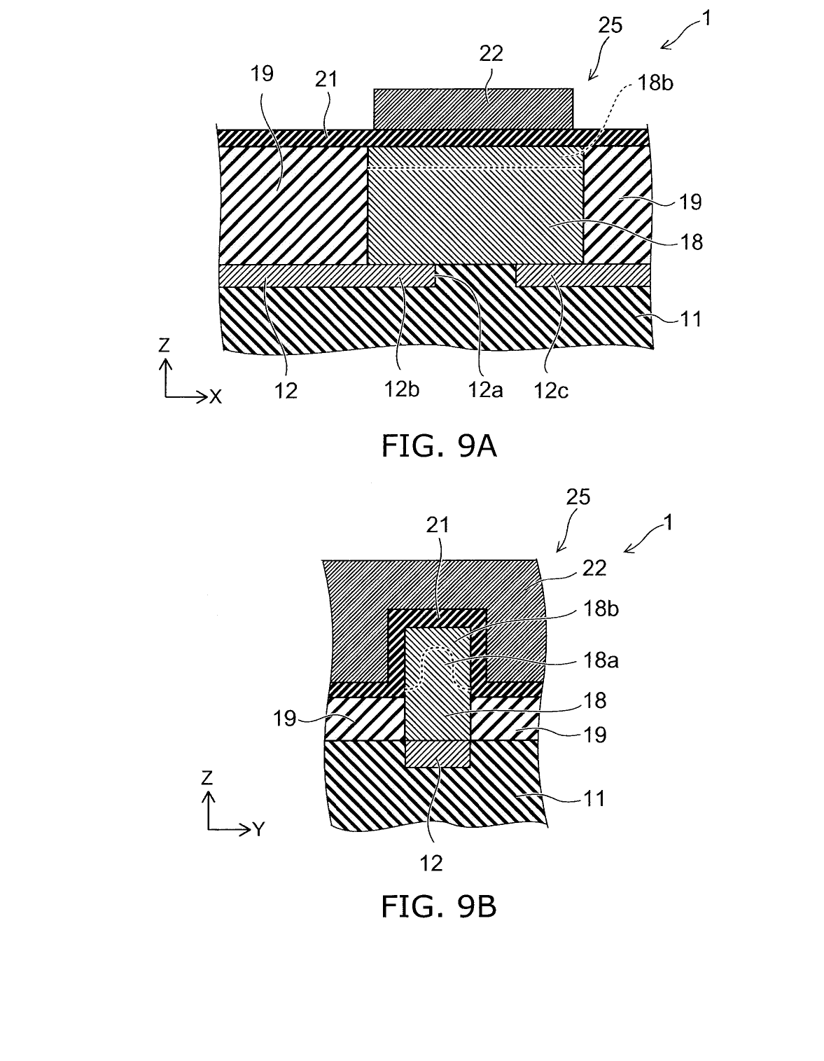

FIG. 9A and FIG. 9B are cross-sectional views illustrating the operations of the memory device according to the embodiment and show mutually-orthogonal cross sections.

For one of the memory cell members 13, by applying a positive voltage such that the bit line 20 becomes positive and the word line 12 becomes negative, a portion of the metal atoms, e.g., the silver atoms, included in the metal supply layer 15 become positive ions and move into the resistance change layer 14. Then, the positive ions bond with electrons supplied from the word line 12 and precipitate as metal atoms. Thereby, a filament (not shown) is formed inside the resistance change layer 14; and the state is switched to a low resistance state (an on-state). Also, by applying a reverse voltage such that the bit line 20 becomes negative and the word line 12 becomes positive, at least a portion of the metal atoms of the filament becomes positive ions and returns to the metal supply layer 15. Thereby, the filament is broken; and the resistance change layer 14 is switched to a high resistance state (an off-state). The memory device 1 stores data corresponding to the resistance states of the resistance change layer 14.

On the other hand, as shown in FIG. 9A and FIG. 9B, a field effect transistor 25 is formed of the word line 12, the semiconductor member 18, the gate insulating film 21, and the gate electrode 22. In the transistor 25, the portion 12b and the portion 12c of the word line 12 function as source/drains; and the semiconductor member 18 functions as a channel. The gate-length direction of the transistor 25 is the X-direction.

Then, the timing of applying the potential to the word line 12 is controlled by the transistor 25. In other words, by applying the positive potential to the gate electrode 22, electrons collect in a portion 18b of the semiconductor member 18 positioned at the vicinity of the gate electrode 22 to become carriers. Thereby, a current flows in the semiconductor member 18 via the portion 18b; and the transistor 25 is switched to the on-state. As a result, the word line 12 conducts; and a potential is applied to the memory cell member 13. It is presumed that a tunneling current flows between the portion 18b of the semiconductor member 18 and the portion 12b and the portion 12c of the word line 12.

Effects of the embodiment will now be described.

In the embodiment, the source/drains of the transistors 25 are formed by utilizing the word lines 12 for integrating the memory cell members 13 in a cross-point configuration. Also, the gate electrode 22 of the transistors 25 is formed simultaneously with the bit lines 20 by patterning the conductive film 33. Thereby, an increase of the number of processes for forming the transistors 25 is suppressed; and the memory device 1 can be formed inexpensively. Also, because the transistors 25 can be arranged at the same arrangement period as the word lines 12, the integration of the transistors 25 can be increased; and the memory device 1 can be downsized.

Also, in the embodiment, the gate insulating film 21 and the gate electrode 22 are disposed not only on the upper surface of the upper portion 18a of the semiconductor member 18 but also on the side surfaces of the upper portion 18a facing the Y-direction. Thereby, as viewed from the X-direction, the configuration of the portion 18b where the carriers collect can be an inverted U-shaped configuration. As a result, compared to the case where the gate insulating film 21 and the gate electrode 22 are disposed only on the upper surface of the upper portion 18a of the semiconductor member 18, the cross-sectional area of the portion 18b can be increased; and the on-state current of the transistor 25 can be increased. Thereby, the drive current for driving the memory cell member 13 increases.

Further, in the embodiment, because it is unnecessary to increase the width, i.e., the length in the Y-direction, of the semiconductor member 18 to increase the drive current, the semiconductor member 18 can be formed to have the same width as the word line 12 and can be arranged in one column along the Y-direction. Thereby, the surface area of the peripheral circuit region Rc can be prevented from increasing.

Thus, according to the embodiment, the performance of the transistor 25 for current control can be improved without increasing the surface area of the peripheral circuit region Rc.

It is sufficient to determine the etched amount of the inter-layer insulating film 19, i.e., the downward extension amount of the gate electrode 22, on the Y-direction side of the semiconductor member 18 according to the balance between the current driving capability and the breakdown voltage necessary for the transistor 25. As the extension amount of the gate electrode 22 is increased, the current driving capability of the transistor 25 improves; but the breakdown voltage between the word line 12 and the gate electrode 22 decreases. However, if the extension amount of the gate electrode 22 is increased, the controllability of the semiconductor member 18 by the gate electrode 22 increases; and the voltage between the word line 12 and the gate electrode 22 can be reduced by this amount. Thereby, the breakdown voltage that is necessary between the word line 12 and the gate electrode 22 can be reduced; and the gate electrode 22 can be extended even further downward. Thus, there is positive feedback acting on the effect of extending the gate electrode 22 downward.

Although an example is illustrated in the embodiment in which the inter-layer insulating film 19 remains between the word line 12 and the gate electrode 22 also at the portion between the semiconductor members 18 to realize the prescribed breakdown voltage, the inter-layer insulating film 19 may be removed completely from this portion if a sufficient breakdown voltage is ensured by only the gate insulating film 21.

### Modification of First Embodiment

A modification of the first embodiment will now be described.

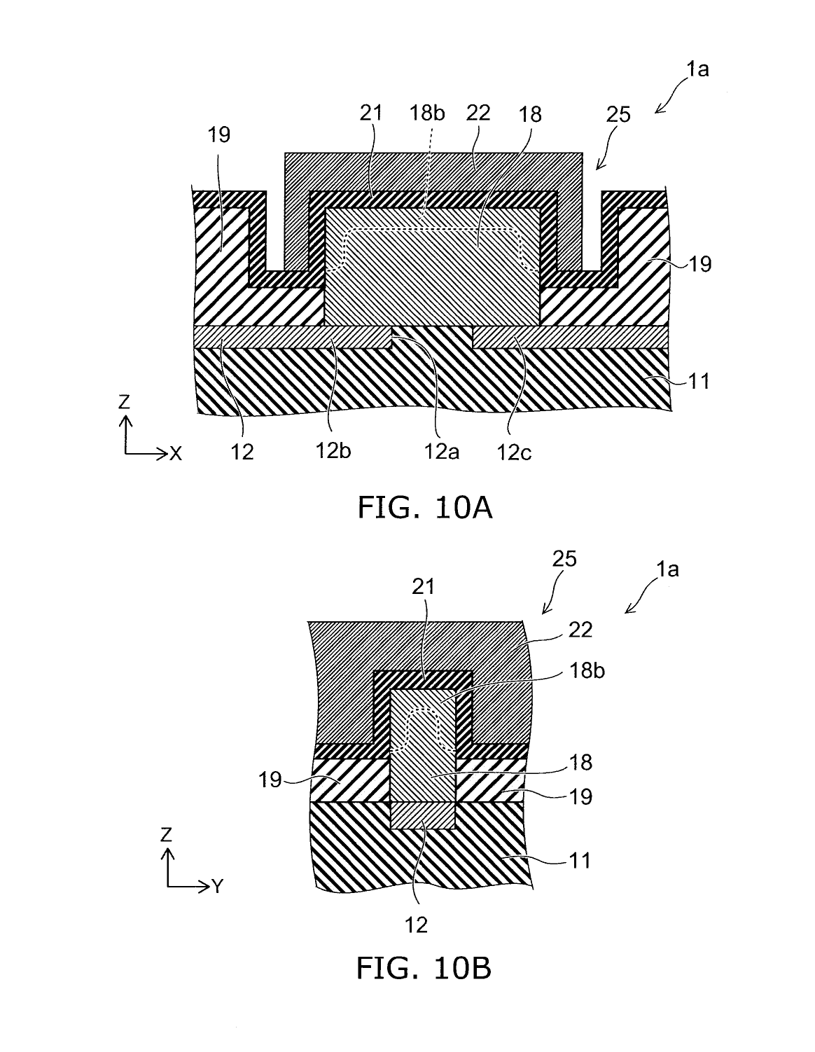

FIG. 10A and FIG. 10B are cross-sectional views illustrating operations of a memory device according to the modification and show mutually-orthogonal cross sections.

In the memory device 1a according to the modification as shown in FIG. 10A and FIG. 10B, the inter-layer insulating film 19 is etched not only on the two Y-direction sides of the semiconductor member 18 but also on the two X-direction sides. Thereby, for the upper portion 18a of the semiconductor member 18, the gate insulating film 21 and the gate electrode 22 are disposed not only on the side surfaces facing the Y-direction but also on the side surfaces facing the X-direction.

As a result, as shown in FIG. 10A, compared to the memory device 1 (referring to FIG. 9A) according to the first embodiment described above, the portion 18b where the carriers collect is formed also at the two X-direction end portions of the upper portion 18a of the semiconductor member 18. In other words, the portion 18b is formed in an inverted cup-like configuration along the upper surface and four side surfaces of the portion 18a. As a result, the current path between the portion 12b of the word line 12 and the portion 18b of the semiconductor member 18 becomes short; the current path between the portion 12c and the portion 18b becomes short; and the on-resistance of the semiconductor member 18 decreases. Thereby, the current driving capability of the transistor 25 can be improved even further. Otherwise, the configuration, the manufacturing method, the operations, and the effects of the modification are similar to those of the first embodiment described above.

### Second Embodiment

A second embodiment will now be described.

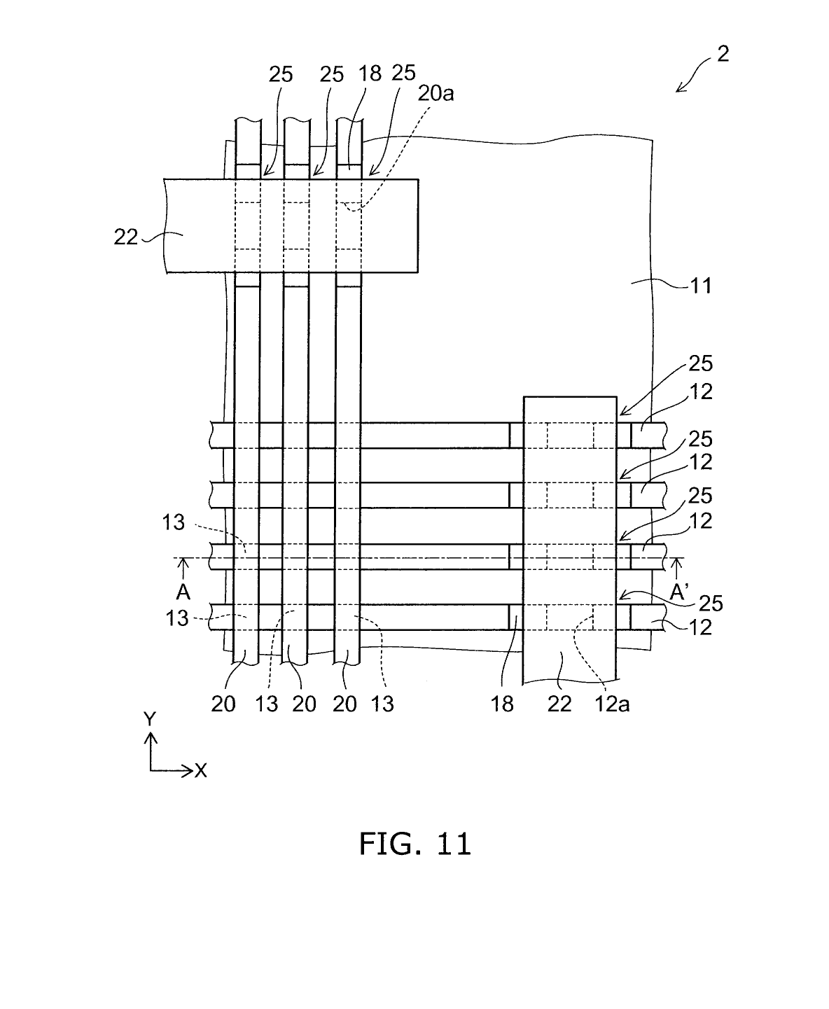

FIG. 11 is a plan view illustrating a memory device according to the embodiment.

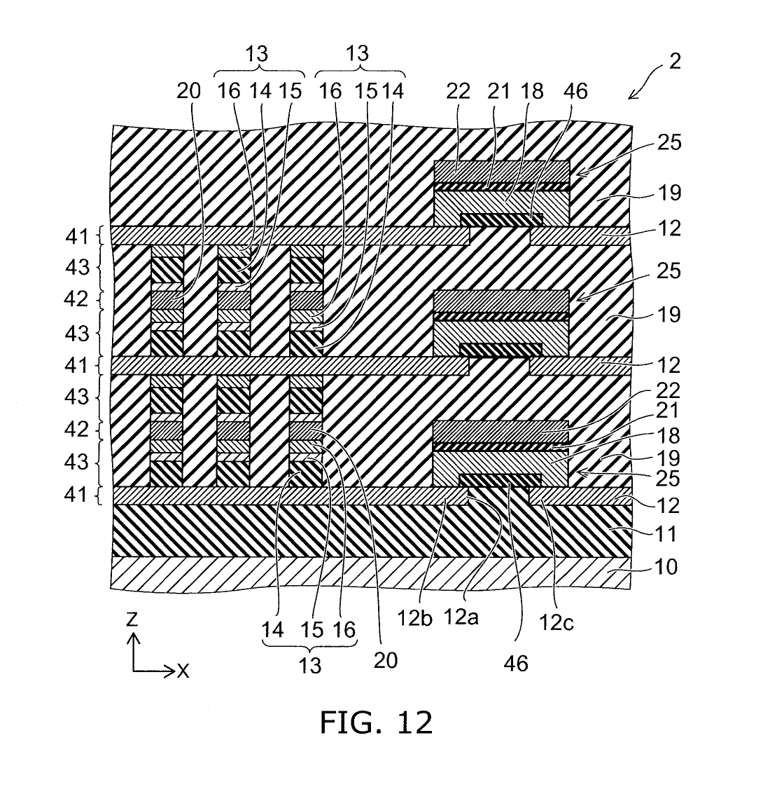

FIG. 12 is a cross-sectional view along line A-A′ shown in FIG. 11.

For easier viewing of the drawing, the inter-layer insulating film 19 and the gate insulating film 21 are not shown in FIG. 11.

In the memory device 2 according to the embodiment as shown in FIG. 11 and FIG. 12, multiple levels of the structure described in the first embodiment described above are stacked along the Z-direction.

Specifically, a word line interconnect layer 41 that is made of the multiple word lines 12 arranged on the same XY plane and a bit line interconnect layer 42 that is made of the multiple bit lines 20 arranged on the same XY plane are arranged alternately along the Z-direction to be separated from each other. Also, a memory cell layer 43 that is made of the multiple memory cell members 13 arranged on the same XY plane is disposed between the word line interconnect layer 41 and the bit line interconnect layer 42. The memory cell member 13 that has a pillar configuration is connected between each of the word lines 12 and each of the bit lines 20.

The configurations of the bit line interconnect layer 42 of the lowermost layer and the structural body below the bit line interconnect layer 42 of the lowermost layer are similar to those of the memory device 1 (referring to FIG. 1A to FIG. 1C) according to the first embodiment described above. However, in the embodiment, an insulating film 46 is provided at the X-direction central portion, i.e., the gate length-direction central portion, of the lower portion of the semiconductor member 18.

Also, the structure of the portion in which the word line interconnect layer 41, the memory cell layer 43, and the bit line interconnect layer 42 are consecutively arranged in order from the lower layer side is similar to the structure of the memory device 1 according to the first embodiment excluding the semiconductor substrate 10 and the inter-layer insulating film 11.

On the other hand, in the structure of the portion in which the bit line interconnect layer 42, the memory cell layer 43, and the word line interconnect layer 41 are consecutively arranged in order from the lower layer side, the stacking order inside each of the memory cell members 13 and the formation position of the transistor 25 are different from those of the configuration of the memory device 1.

Specifically, in the memory cell members 13 belonging to the memory cell layers 43 for which the bit line interconnect layer 42 is disposed below and the word line interconnect layer 41 is disposed above, the metal supply layer 15, the resistance change layer 14, and the stopper layer 16 are arranged in order from the lower layer side. In other words, in each of the memory cell members 13, the stopper layer 16 is disposed in the uppermost layer; and the metal supply layer 15 is disposed further on the bit line 20 side than is the resistance change layer 14.

Also, in the memory cell layers 43 for which the word line interconnect layer 41 is disposed above, the transistor 25 is formed to be interposed at the bit line 20. In other words, a divided portion 20a is made in the bit line 20; the semiconductor member 18 is provided to straddle the divided portion 20a; and the gate insulating film 21 and the gate electrode 22 are disposed on the upper surface of the upper portion 18a of the semiconductor member 18 and on the side surfaces of the upper portion 18a facing the X-direction. Other than the gate-length direction being the Y-direction, the configuration of the transistor 25 interposed at the bit line 20 is similar to the configuration of the transistor 25 interposed at the word line 12 described above. Also, the composition and thickness of the gate electrode 22 of the transistor 25 interposed at the bit line 20 are the same as the composition and thickness of the word line 12 disposed one level above the bit line 20.

The memory device 2 according to the embodiment can be manufactured by repeating the manufacturing processes described in the first embodiment described above.

Effects of the embodiment will now be described.

Because the memory cell members 13 can be stacked in the Z-direction in the embodiment, the integration of the memory cell members 13 can be increased.

Also, in the embodiment, the channels of the transistors 25 are formed not in the semiconductor substrate 10 but in the semiconductor members 18. Thereby, the transistors 25 can be formed for each memory cell layer 43. As a result, the transistors 25 also can be stacked upward as the memory cell members 13 are stacked upward. Thereby, even in the case where the number of stacks of the memory cell members 13 increases, the surface area of the peripheral circuit region Rc does not increase; and the surface area occupied by the peripheral circuit region Rc on the chip also does not increase. Accordingly, by stacking the memory cell members 13, higher integration can be realized while suppressing the increase of the surface area for the entire memory device 2.

Further, in the embodiment, the insulating film 46 is provided at the gate length-direction central portion of the lower portion of the semiconductor member 18. Thereby, the portion of the semiconductor member 18 where the controllability by the gate electrode 22 is weak can be removed; and the leak current when OFF can be suppressed.

Otherwise, the configuration, the manufacturing method, the operations, and the effects of the embodiment are similar to those of the first embodiment described above.

### First Modification of Second Embodiment

A first modification of the second embodiment will now be described.

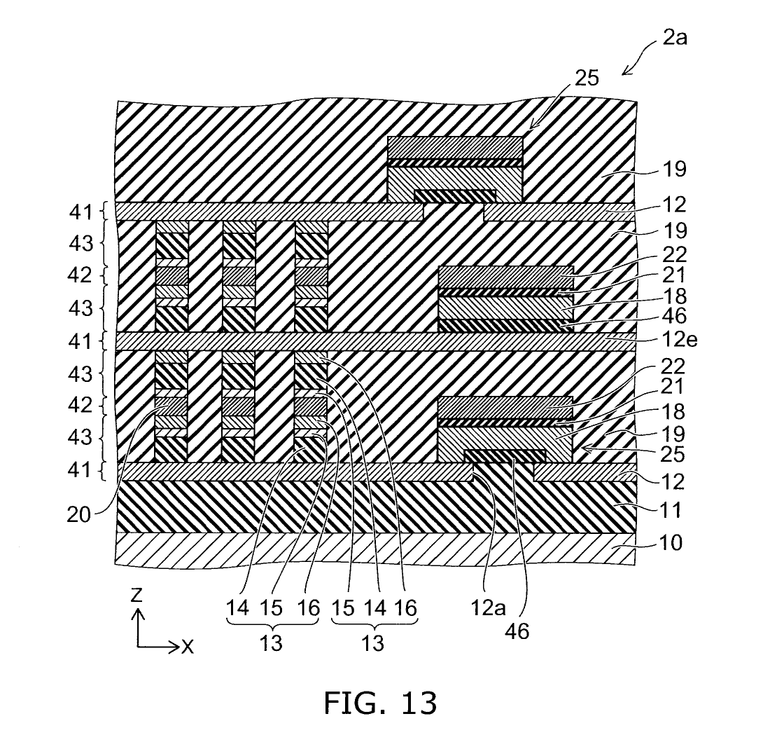

FIG. 13 is a cross-sectional view illustrating a memory device according to the modification.

In the memory device 2a according to the modification as shown in FIG. 13, the position in the X-direction of the transistor 25 interposed at the word line 12 is different between the memory cell layers 43 for which the word line interconnect layer 41 is disposed below and the bit line interconnect layer 42 is disposed above. Also, a word line 12e exists in which the divided portion 12a is not made; and the insulating film 46 is interposed on the entire surface between the word line 12e and the semiconductor member 18. Therefore, the transistor 25 is not interposed at the word line 12e. Accordingly, in the memory device 2a, the word line 12 that has the transistor 25 interposed coexists with the word line 12e that does not have the transistor 25 interposed.

Similarly, the position in the Y-direction of the transistor 25 interposed at the bit line 20 is different between the memory cell layers 43 for which the bit line interconnect layer 42 is disposed below and the word line interconnect layer 41 is disposed above. Also, the bit line 20 that has the transistor 25 interposed coexists with the bit line 20 that does not have the transistor 25 interposed.

Otherwise, the configuration, the manufacturing method, the operations, and the effects of the modification are similar to those of the second embodiment described above.

### Second Modification of Second Embodiment

A second modification of the second embodiment will now be described.

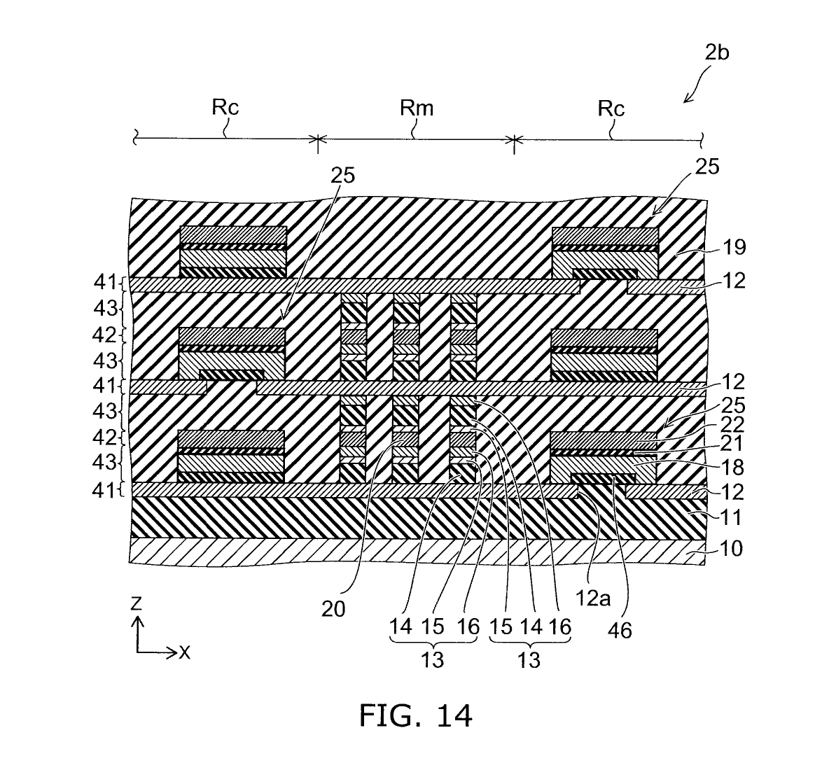

FIG. 14 is a cross-sectional view illustrating a memory device according to the modification.

In the memory device 2b according to the modification as shown in FIG. 14, the transistors 25 interposed at the word lines 12 are disposed alternately at the two X-direction sides of the memory cell region Rm between the memory cell layers 43 for which the word line interconnect layer 41 is disposed below and the bit line interconnect layer 42 is disposed above. In other words, for the word lines 12 arranged in the Z-direction, the transistors 25 are disposed alternately on the two X-direction sides of the memory cell region Rm; and for the word lines 12 arranged in the Y-direction as well, the transistors 25 are disposed alternately on the two X-direction sides of the memory cell region Rm.

Similarly, the transistors 25 interposed at the bit lines 20 are disposed alternately on the two Y-direction sides of the memory cell region Rm between the memory cell layers 43 for which the bit line interconnect layer 42 is disposed below and the word line interconnect layer 41 is disposed above.

Thereby, the design of the layout of the interconnects (not shown) for applying the potential to the gate electrodes 22 of the transistors 25 becomes easy.

Otherwise, the configuration, the manufacturing method, the operations, and the effects of the modification are similar to those of the second embodiment described above.

According to the embodiments described above, a memory device that is small and has a high current driving capability of the switching elements and a method for manufacturing the memory device can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A memory device, comprising:
a first interconnect, a divided portion being formed in the first interconnect;
a memory cell member provided on the first interconnect;
a second interconnect provided on the memory cell member;
a semiconductor member provided on the first interconnect to be connected between portions of the first interconnect on two sides of the divided portion;
an insulating film covering an upper surface of the semiconductor member and a side surface of at least an upper portion of the semiconductor member; and
an electrode provided on the insulating film to cover the upper surface of the semiconductor member and the side surface of the at least an upper portion of the semiconductor member with the insulating film interposed.

2. The memory device according to claim 1, wherein
a composition of the electrode is equal to a composition of the second interconnect, and
a thickness of the electrode is equal to a thickness of the second interconnect.

3. The memory device according to claim 1, wherein the insulating film and the electrode cover a side surface of the semiconductor member facing a direction intersecting an extension direction of the first interconnect.

4. The memory device according to claim 1, further comprising an inter-layer insulating film, a portion of the inter-layer insulating film being disposed between the first interconnect and the insulating film.

5. The memory device according to claim 1, wherein an extension direction of the second interconnect intersects an extension direction of the first interconnect.

6. The memory device according to claim 1, wherein the semiconductor member includes silicon.

7. The memory device according to claim 1, wherein the memory cell member includes:
a resistance change layer; and
a metal supply layer including a metal capable of moving through the resistance change layer.

8. The memory device according to claim 7, wherein
the resistance change layer includes silicon, and
the metal is one type of material selected from the group consisting of silver, copper, nickel, aluminum, and titanium.

9. A memory device, comprising:
a first interconnect extending in a first direction, a first divided portion being formed in the first interconnect;
a first memory cell member provided on the first interconnect;
a second interconnect provided on the first memory cell member to extend in a second direction intersecting the first direction, a second divided portion being formed in the second interconnect;
a first semiconductor member provided on the first interconnect to be connected between portions of the first interconnect on two sides of the first divided portion;
a first insulating film covering an upper surface of the first semiconductor member and a side surface of at least an upper portion of the first semiconductor member;
a first electrode provided on the first insulating film to cover the upper surface of the first semiconductor member and the side surface of the at least an upper portion of the first semiconductor member with the first insulating film interposed;
a second memory cell member provided on the second interconnect;
a third interconnect provided on the second memory cell member to extend in the first direction;
a second semiconductor member provided on the second interconnect to be connected between portions of the second interconnect on two sides of the second divided portion;
a second insulating film covering an upper surface of the second semiconductor member and a side surface of at least an upper portion of the second semiconductor member; and
a second electrode provided on the second insulating film to cover the upper surface of the second semiconductor member and the side surface of the at least an upper portion of the second semiconductor member with the second insulating film interposed.

10. The memory device according to claim 9, wherein
a composition of the first electrode is equal to a composition of the second interconnect,
a thickness of the first electrode is equal to a thickness of the second interconnect,
a composition of the second electrode is equal to a composition of the third interconnect, and
a thickness of the second electrode is equal to a thickness of the third interconnect.

11. The memory device according to claim 9, wherein the first memory cell member and the second memory cell member each include:
a resistance change layer; and
a metal supply layer including a metal capable of moving through the resistance change layer.

12. A method for manufacturing a memory device, comprising:
forming a first interconnect, a divided portion being formed in the first interconnect;
forming a semiconductor member on the first interconnect to be connected between portions of the first interconnect on two sides of the divided portion, and forming a memory cell member on a portion of the first interconnect separated from the divided portion;
forming an inter-layer insulating film between the semiconductor member and the memory cell member to expose an upper surface of the memory cell member, an upper surface of the semiconductor member, and a side surface of at least an upper portion of the semiconductor member;
forming an insulating film on the exposed surfaces of the semiconductor member; and
forming a second interconnect on the memory cell member, and forming an electrode on the insulating film.

13. The memory device according to claim 12, wherein the forming of the electrode includes:
forming a conductive film; and
forming the second interconnect and the electrode by selectively removing the conductive film.

14. The method for manufacturing the memory device according to claim 12, wherein the forming of the inter-layer insulating film includes:
filling an insulating material between the semiconductor member and the memory cell member; and
removing a portion of the insulating material to expose the side surface of the at least an upper portion of the semiconductor member.

15. The method for manufacturing the memory device according to claim 14, wherein a side surface of a lower portion of the semiconductor member is not exposed when removing the portion of the insulating material.

16. The method for manufacturing the memory device according to claim 12, wherein the forming of the memory cell member includes:
forming a semiconductor film in a region including a region directly above the divided portion;
stacking a metal supply layer and a resistance change layer on the entire surface, the metal supply layer including a metal capable of moving through the resistance change layer;
removing the metal supply layer and the resistance change layer on the semiconductor film;
selectively removing the semiconductor film to cause the semiconductor film to remain in a region directly above the first interconnect to straddle the divided portion, and selectively removing the metal supply layer and the resistance change layer to cause the metal supply layer and the resistance change layer to remain in a portion of a region directly above the first interconnect.

17. The method for manufacturing the memory device according to claim 12, wherein
the first interconnect is formed to extend in a first direction, and
the second interconnect is formed to extend in a second direction intersecting the first direction.

18. The method for manufacturing the memory device according to claim 17, wherein
the forming of the second interconnect includes forming one other divided portion in the second interconnect at a position separated from a region directly above the memory cell member, and
the method further comprises:
forming one other semiconductor member on the second interconnect to be connected between portions of the second interconnect on two sides of the one other divided portion, and forming one other memory cell member on the second interconnect in a region directly above the memory cell member;
forming one other inter-layer insulating film between the one other semiconductor member and the one other memory cell member to expose an upper surface of the one other memory cell member, an upper surface of the one other semiconductor member, and a side surface of at least an upper portion of the one other semiconductor member;
forming one other insulating film on the exposed surfaces of the one other semiconductor member; and
forming a third interconnect on the one other memory cell member to extend in the first direction, and forming one other electrode on the one other insulating film.
